(19) United States
(12) Patent Application Publication
(10) Pub. No.: US 2026/0227958 A1
(43) Pub. Date: Aug. 6, 2026

(54) ADAPTIVE FAULT INJECTION FACILITATION SYSTEMS, METHODS, AND COMPUTER PROGRAM PRODUCTS

(71) Applicant: IOActive, Inc., Seattle, WA (US)

(72) Inventors: Gabriel GONZALEZ, Madrid (ES); Ramiro PAREJA-VEREDAS, Madrid (ES)

(73) Assignee: IOActive, Inc., Seattle, WA (US)

(21) Appl. No.: 19/468,879

(22) Filed: Feb. 3, 2026

Related U.S. Application Data
(60) Provisional application No. 63/753,038, filed on Feb. 3, 2025.

(51) Int. Cl. G06F 7/58; G01R 31/3177; G06F 11/263; G06F 11/3668; G06F 11/3698

(52) U.S. Cl. CPC G06F 7/58; G01R 31/3177; G06F 11/263; G06F 11/3696; G06F 11/3698

(57) ABSTRACT

Systems, methods, and computer program products are disclosed in regard to selectively adapting a subset of parametric test sequences respectively applied to multiple units-in-test (UITs). After an anomaly is exhibited by a first UIT undergoing a first parametric sequence but not by a second UIT undergoing a second parametric sequence. Adaptive coordination across UITs is thereby enabled, allowing streamlined sequence selection and expanded detection coverage. Related systems and computer program products configured to facilitate this coordinated validation process are also described.

### RELATED APPLICATIONS

This application claims the benefit of U.S. Prov. App. No. 63/753,038 (entitled “Adaptive Fault Injection Facilitation Systems and Methods”) filed on Feb. 3, 2025.

### FIELD OF THE INVENTION

The disclosure relates to testing and verification of electronic systems and to orchestration of controlled fault-injection campaigns across distributed special-purpose controllers coupled to corresponding units in test.

### BACKGROUND

There is a need to run fault-injection campaigns across many devices in parallel without saturating host-to-controller links, while preserving reproducibility across facilities, and while reacting promptly to behavior observed on a unit in test. Existing systems tend to require streaming full parameter sequences to each controller, lack a mechanism that would enable exact replay across sites, and otherwise limit testing quality and throughput.

### FIGURE SUMMARY

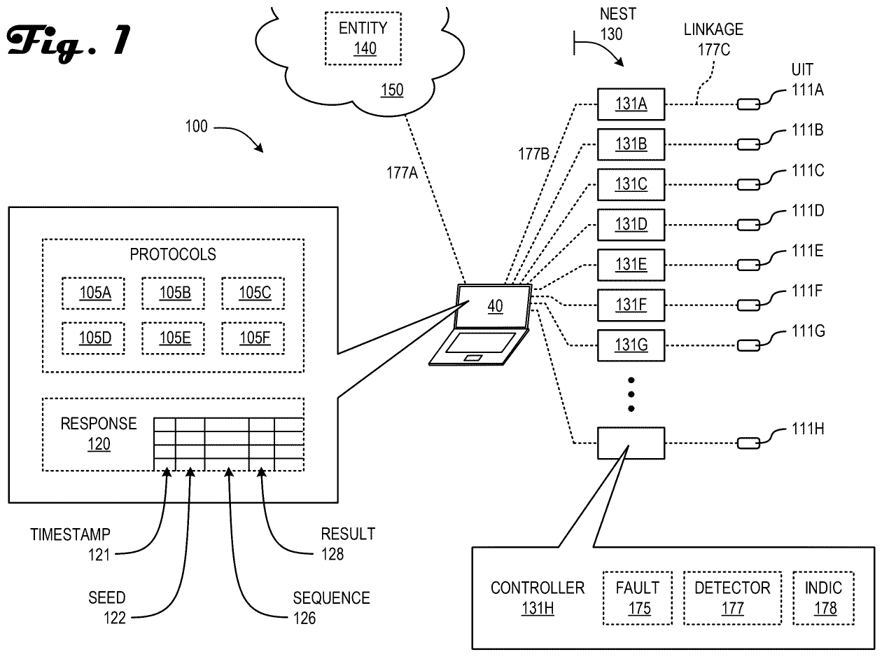

Referring now to FIG. 1, there is shown a system in which one or more technologies may be incorporated.

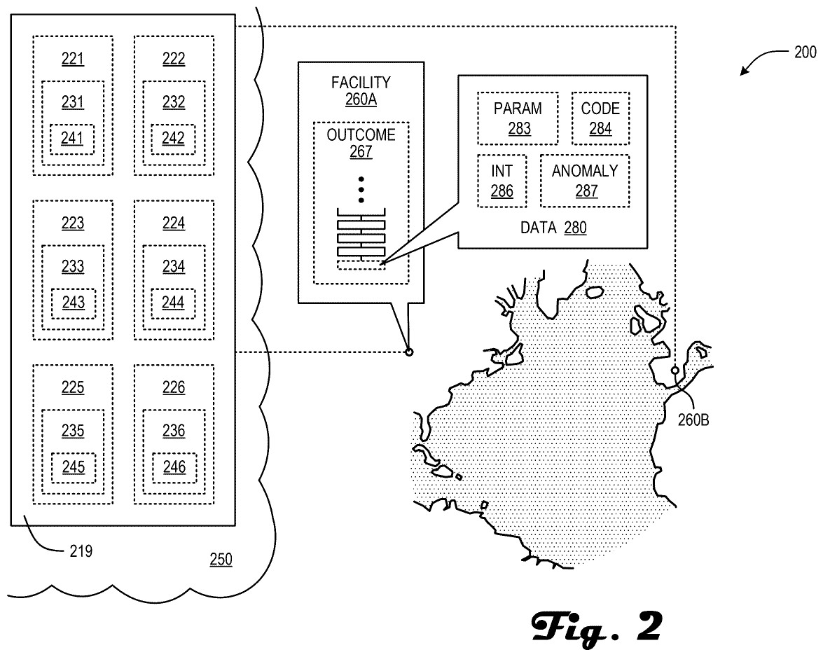

Referring now to FIG. 2, there is shown a system that allows one or more facilities in North America to interact with one or more facilities in Spain in which one or more technologies may be incorporated, one that may implement or interact with the system of FIG. 1.

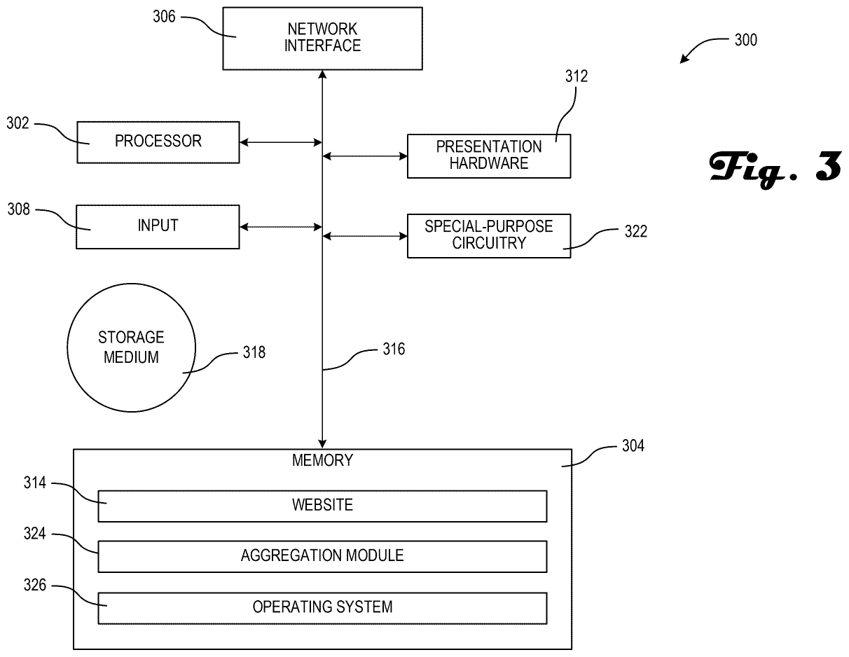

Referring now to FIG. 3, there is shown a server in which one or more animations may be incorporated.

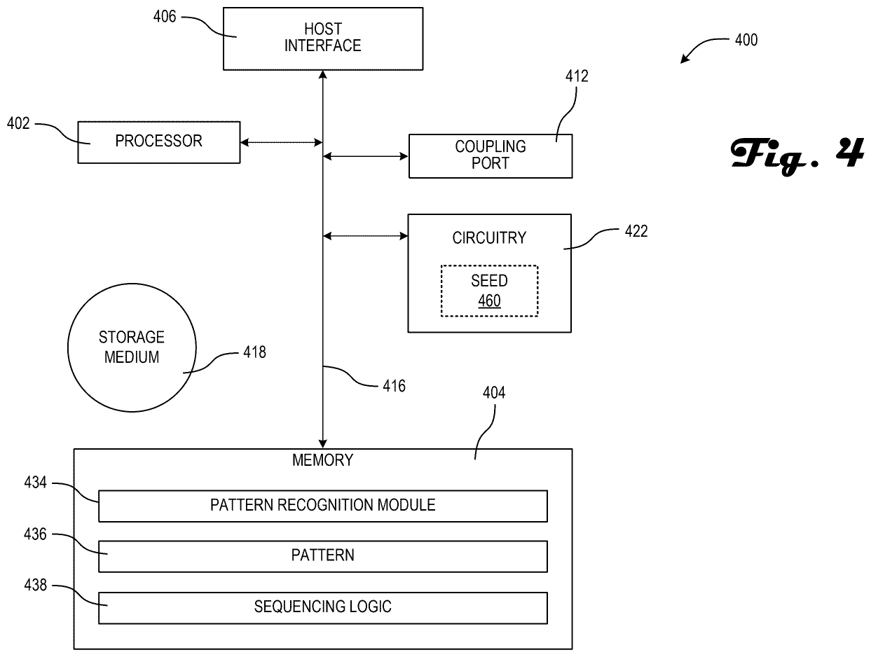

Referring now to FIG. 4, there is shown a special-purpose controller in which one or more technologies may be incorporated.

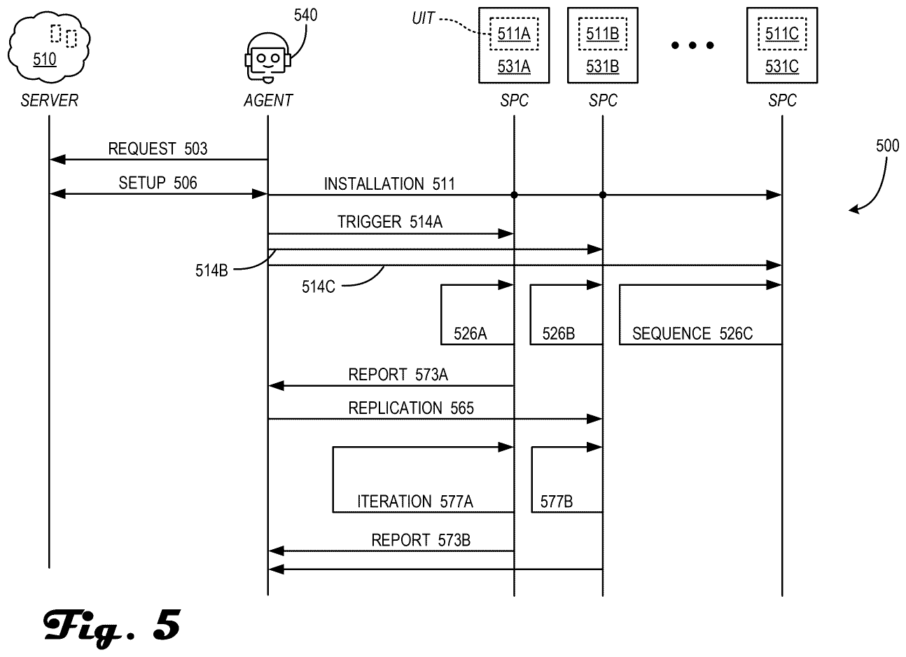

Referring now to FIG. 5, there is shown a testing scenario and data flow in which one or more technologies may be incorporated.

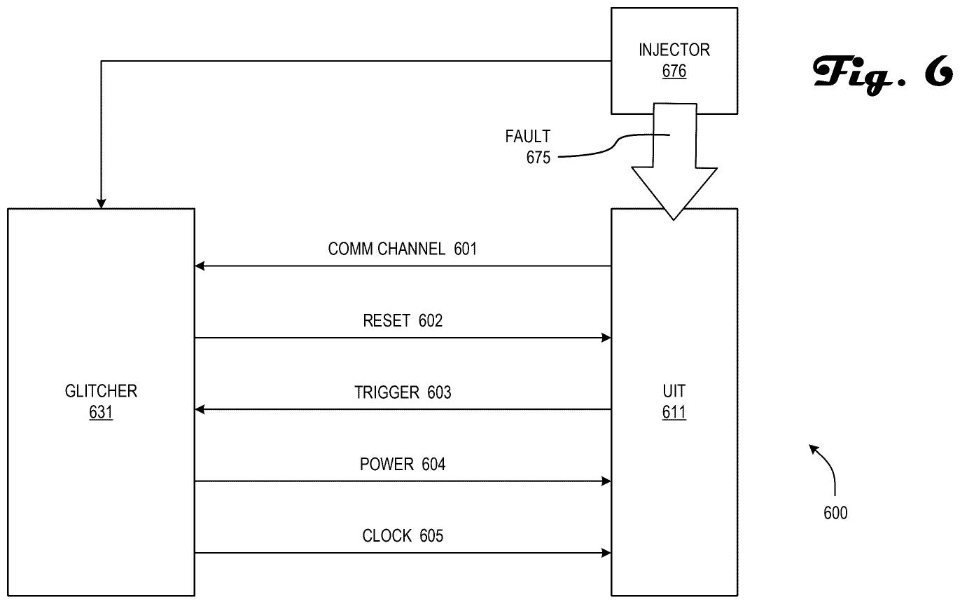

Referring now to FIG. 6, there is shown a system in which one or more technologies may be incorporated.

### DETAILED DESCRIPTION

The detailed description that follows is represented largely in terms of processes and symbolic representations of operations by conventional computer components, including a processor, memory storage devices for the processor, connected display devices, and input devices. Furthermore, some of these processes and operations may utilize conventional computer components in a heterogeneous distributed computing environment, including remote file servers, computer servers, and memory storage devices.

It is intended that the terminology used in the description presented below be interpreted in its broadest reasonable manner, even though it is being used in conjunction with a detailed description of certain example embodiments. Although certain terms may be emphasized below, any terminology intended to be interpreted in any restrictive manner will be overtly and specifically defined as such.

The phrases “in one embodiment,” “in various embodiments,” “in some embodiments,” and the like are used repeatedly. Such phrases do not necessarily refer to the same embodiment. The terms “comprising,” “having,” and “including” are synonymous, unless the context dictates otherwise.

“Above,” “after,” “anomalous,” “at least,” “based,” “by virtue of,” “calibrated,” “contemporaneously,” “determined,” “effective,” “first,” “functional,” “improved,” “in test,” “indicative,” “instantiated,” “intermittent,” “into,” “invoked,” “local,” “most,” “multiple,” “nominal,” “normal,” “numerous,” “other,” “parametric,” “partly,” “potentially,” “rather than,” “readable,” “remote,” “respective,” “returned,” “sampled,” “second,” “single,” “some,” “special-purpose,” “transitory,” “transistor-based,” “triggering,” “undergoing,” “vetted,” “wherein,” “wired,” “without,” or other such descriptors herein are used in their normal yes-or-no sense, not merely as terms of degree, unless context dictates otherwise. In light of the present disclosure, those skilled in the art will understand from context what is meant by “remote” and by other such positional descriptors used herein. Likewise, they will understand what is meant by “partly based” or other such descriptions of dependent computational variables/signals. Circuitry is “invoked” as used herein if it is called on to undergo voltage state transitions so that digital signals are transmitted therefrom or therethrough unless context dictates otherwise. Software is “invoked” as used herein if it is executed/triggered unless context dictates otherwise. As used herein “causing” is not limited to a proximate cause but also enabling, conjoining, or other actual causes of an event or phenomenon. “Instances” of an item may or may not be identical or similar to each other, as used herein.

Terms like “processor,” “center,” “unit,” “computer,” or other such descriptors herein are used in their normal sense, in reference to an inanimate structure. Such terms do not include any people, irrespective of their location or employment or other association with the thing described, unless context dictates otherwise. “For” is not used to articulate a mere intended purpose in phrases like “circuitry for” or “instruction for,” moreover, but is used normally, in descriptively identifying special purpose software or structures.

Counts or percentages of parameters described herein include calibration or other dimensional quantifications (e.g. in units of voltage or time) and anomaly-related event counts. Generally they do not take value groupings (e.g. vectors), non-quantified numbers, or binary component values separately into account, unless context dictates otherwise.

Reference is now made in detail to the description of the embodiments as illustrated in the drawings. While embodiments are described in connection with the drawings and related descriptions, there is no intent to limit the scope to the embodiments disclosed herein. On the contrary, the intent is to cover all alternatives, modifications and

equivalents. In alternate embodiments, additional devices, or combinations of illustrated devices, may be added to, or combined, without limiting the scope to the embodiments disclosed herein.

Referring now to FIG. 1, there is shown a system 100 in which a local host 40 is configured to interact with one or more remote entities 140 (e.g. expert service providers) via linkages 177A with one or more networks 150. Local host 40 also interacts with multiple special-purpose controllers (SPCs) 131A-H via corresponding (instances of) local linkages 177B so that most or all of the units in test (UITs) 111A-H can undergo non-identical or other non-synchronized testing under the respective control of the numerous special-purpose controllers (SPCs) 131 of the nest 130. “Numerous” as used herein refers to more than ten unless context dictates otherwise. “Local” as used herein may refer to locations within a single facility or separated by less than 500 meters (or both) unless context dictates otherwise. A “nest” as used herein refers to numerous local controllers configured to vet nominally identical components in test. Each of the depicted special-purpose controllers 131A-H is wired to or otherwise has a linkage 177C with a corresponding one of the depicted UITs 111A-H, for example, and may include one or more instances of faults 175, of embedded event detectors 177, or of other indications 178 described herein. Events within each special-purpose controller are filtered or otherwise distilled so that responses 120 aggregated at host 40 are recorded only selectively. Each such event may correspond to a record comprising one or more instances of timestamps 121, of applied seeds 122 or parametric sequences 126, or of results 128 characterizing an overall performance of components in test. Various tools and protocols 105A-F are described that can facilitate such characterization.

Referring now to FIG. 2, there is shown a system 200 that allows one or more facilities 260A in North America to interact with one or more facilities 260B in Spain in which one or more technologies may be incorporated, one that may overlap or interact with the system of FIG. 1. In the interest of concision and according to standard usage in information management technologies, the functional attributes of modules described herein are set forth in natural language expressions. It will be understood by those skilled in the art that such expressions (functions or acts recited in English, e.g.) adequately describe structures identified below so that no undue experimentation will be required for their implementation. For example, any records of outcomes 267 or other informational data identified herein may be represented digitally as a voltage configuration on one or more electrical nodes (conductive pads of an integrated circuit, e.g.) of an event-sequencing structure without any undue experimentation. Each electrical node is highly conductive, having a corresponding nominal voltage level that is spatially uniform generally throughout the node (within a device or local system as described herein, e.g.) at relevant times (at clock transitions, e.g.). Such nodes (lines on an integrated circuit or circuit board, e.g.) may each comprise a forked or

other signal path adjacent one or more transistors. Moreover, many Boolean values (yes-or-no decisions, e.g.) may each be manifested as either a “low” or “high” voltage, for example, according to a complementary metal-oxide-semiconductor (CMOS), emitter-coupled logic (ECL), or other common semiconductor configuration protocol. In some contexts, for example, one skilled in the art will recognize an “electrical node set” as used herein in reference to one or more electrically conductive nodes upon which a voltage configuration (of one voltage at each node, for example, with each voltage characterized as either high or low) manifests a yes/no decision or other digital data.

Such circuitry 219 may comprise one or more integrated circuits (ICs), for example, optionally mounted on one or more circuit boards that implement an event-sequencing structure as generally described in U.S. Pat. Pub. No. 2015/0094046 but configured as described herein. Transistor-based circuitry 219 may (optionally) include one or more instances of interface modules 221, for example, (each) including an electrical node set 231 upon which protocols 105 or other informational data are represented digitally as a corresponding voltage configuration 241. Transistor-based circuitry 219 may likewise include one or more instances of download modules 222, for example, including an electrical node set 232 upon which request, requirement, or other informational data is represented digitally as a corresponding voltage configuration 242. Transistor-based circuitry 219 may (optionally) likewise include one or more instances of triggering modules 223, for example, including an electrical node set 233 upon which timing or other informational data is represented digitally as a corresponding voltage configuration 243. Transistor-based circuitry 219 may likewise include one or more instances of control modules 224, for example, including an electrical node set 234 upon which event sequencing criteria or other informational data is represented digitally as a corresponding voltage configuration 244. Transistor-based circuitry 219 may likewise include one or more instances of update modules 225, for example, including an electrical node set 235 upon which versions, permutations, counts, or other informational data is represented digitally as a corresponding voltage configuration 245. Transistor-based circuitry 219 may likewise include one or more instances of monitoring modules 226, for example, including an electrical node set 236 upon which completion criteria or other informational data is represented digitally as a corresponding voltage configuration 246. Operating parameters 283 and first device-executable code 284 may, for example, be downloaded to a facility 260A for use in evaluation a product or component thereof as to its vulnerability to a voltage-glitch-related attack. During or after testing one or more intermittencies 286 or other patterns of anomalies 287 may be provided, together with detailed data describing such testing and its outcomes 267. As used herein an “anomaly” refers to a repeatable or other occurrence revealing a potential security risk exhibited by a product or component undergoing a vetting protocol 105A, unless context dictates otherwise.

In some variants an inventive validation method includes establishing (e.g. by a first triggering module 223 or installer) numerous special-purpose controllers 131 operably coupled to a single local host 40. For example a first special-purpose controller 131A (in some variants) is operably coupled with and configured to implement a first parametric sequence 126 upon a first unit in test (UIT) 111A by virtue of the first special-purpose controller 131A

deterministically generating numerous respective sets of glitch attempt parameters 283 (at least partly) based on first device-executable code 284 provided by a remote entity and configured locally. Contemporaneously with this implementation, a second special-purpose controller 131B configured to implement another parametric sequence 126 upon another UIT 111B by virtue of the controller 131B deterministically generating (contemporaneously or otherwise) its glitch attempt parameters 283 likewise based on the first device-executable code 284. The parallel or other coordinated validation method also includes obtaining, by a first monitoring module 226, a first test result 128 indicating one or more flaw-indicative anomalies 287 of the first parametric sequence 126 upon the first UIT 111A.

The coordinated validation method also includes causing, by a first control module 224, the second special-purpose controller 131B to implement the first parametric sequence 126 upon the second UIT 111B based on the one or more flaw-indicative anomalies 287 of (having applied) the first parametric sequence 126 upon the first UIT 111A and partly based on an explicit or other indication 178 that no flaw-indicative anomalies 287 have yet been detected by the second special-purpose controller 131B.

Referring now to FIG. 3, there is shown a server 300 in which one or more technologies may be implemented. Server 300 may include one or more instances of processors 302, of memories 304, of user inputs 308, and of (display screens or other) presentation hardware 312 all interconnected along with the network interface 306 via a bus 316. One or more network interfaces 306 allow server 300 to connect via the Internet or other networks 150, 250). Memory 304 generally comprises a random-access memory (“RAM”), a read only memory (“ROM”), and a permanent mass storage device, such as a disk drive.

Memory 304 may contain one or more instances of websites 314, of aggregation modules 324, of operating systems 326, or of other informational data described herein. These and other software components may be loaded from a non-transitory computer readable storage medium 318 into memory 304 of the server 300 using a drive mechanism (not shown) associated with a non-transitory computer readable storage medium 318. In some embodiments, software or other digital components may be loaded via the network interface 306, rather than via a computer readable storage medium 318. Special-purpose circuitry 322 may, in some variants, include some or all of the event-sequencing logic described herein. In some embodiments server 300 may include many more components than those shown in FIG. 3, but it is not necessary that all conventional components of a server be shown in order to disclose an illustrative embodiment.

Referring now to FIG. 4, there is shown a special-purpose controller 400 (e.g. implemented as an application-specific integrated circuit) in which one or more technologies may be implemented. SPC 400 may include one or more instances of processors 402, of memories 404, and of (sockets, signal lines, or other) coupling ports 412 all interconnected along with a host interface 406 via a bus 416. One or more host interfaces 406 allow SPC 400 to connect via a (wired or other) linkage 177C. Memory 404 generally comprises a random-access memory (“RAM”), a read only memory (“ROM”), and a non-volatile mass storage device, such as a disk drive.

Memory 404 may contain one or more instances of pattern recognition modules 434 or other device-executable code 284; of patterns 436 signaling a diagnostic indication 178 or other criteria described herein; or other such event sequencing logic 438. These and other digital components may be loaded from a non-transitory computer readable storage medium 418 into memory 404 of the SPC 400 using a drive mechanism (not shown) associated with a non-transitory computer readable storage medium 418. In some embodiments, software or other digital components may be loaded via a host interface 406, rather than via a computer readable storage medium 418. Special-purpose circuitry 422 (implementing voltage spikes or deterministic sequence generation based on one or more seeds 460, e.g.) may, in some variants, include some or all of the above-described modules 221-226. In some embodiments SPC 400 may include many more components than those shown in FIG. 4, but it is not necessary that all conventional components of a mobile device be shown in order to disclose an illustrative embodiment.

Referring now to FIG. 5, there is shown a testing scenario and data flow 500 in which one or more software agents 540 are configured to use one or more protocols 105A-F for interacting with one or more remote servers 510 and numerous local special-purpose controllers 531 each configured to test one or more UITs 511 through its respective electrical linkages 177C. For example a first agent 540 in a first facility 260A may transmit a download request 503 to one or more servers 510 in an overseas facility 260B, triggering an interactive setup 506 that allows an installation 511 of operating parameters 283 and device-executable code 284 to each of the controllers 531A-C.

This allows first agent 540 to send test sequence triggers 514A-C to each of the controllers 531, commencing numerous iterations of test sequences 526A-C each including an embedded automatic pattern recognition protocol 434 (e.g. locally implemented in a special-purpose controller 531 rather than its local host 40). Once the pattern recognition protocol 434 detects a report-triggering pattern 436 (e.g. a fault response anomaly 287, countdown expiration, or other client-defined indication 178) a report 573A thereof is returned to first agent 540 which responds by signaling a replication 565 of the test sequence 526A that was in use at the first controller 531A to one or more other controllers 531 that have not detected any fault response anomalies 287. After numerous additional iterations 577 of that test sequence 526A are performed concurrently on multiple controllers 531, reports 573B of all such fault response anomalies 287 are distilled (e.g. summarized as one or more parameters 283 applied by code 284, one or more intermittencies 286 or other anomalies 287, or other related testing data 284).

Referring now to FIG. 6, there is shown a system 600 in which a local glitcher 631 or other controller 131 is configured to interact directly or otherwise with one or more remote entities 140 with one or more networks 150, 650. In some variants a local host 40 also interacts with multiple glitchers or other special-purpose controllers (SPCs) 131 via corresponding local linkages like those of FIG. 1. In some variants one or more local units in test (UITs) 611 can undergo non-synchronized testing under the respective control of an array of glitchers 631.

As shown each glitcher 631 can be configured to configure and trigger a predefined glitch 675 via a calibrated injector 676 directly into a UIT 611 as shown. Depending on the implementation such glitches may include a LASER perturbation or a conventional Electromagnetic Fault Injection (EMFI), for example, or may form part of a programmatic attack sequence as described herein. For example as shown each glitcher 631 can be configured with a comm channel linkage 601 by which the UIT 611 communicates to the glitcher 631 or other controller 131. Likewise glitcher 631 can be configured with a reset linkage 602 by which the UIT 611 can receive a reset signal or a trigger linkage 603 by which the UIT 611 can transmit a trigger (or both) as part of the attack sequence. Likewise the sequence may cause one or more programmatic faults 175 delivered to the UIT 611 through a special-purpose power linkage 604 or clock linkage 605 as shown. Alternatively or additionally, in some campaigns one or more such special-purpose linkages 601-605 may be omitted or configured to operate conventionally. (As used herein a “campaign” may comprise a coordinated validation of numerous UIT's in which an anomalous outcome of the testing of some triggers, without any interim human involvement, a programmatic alteration of how others of the UIT's are tested.)

Referring again to FIGS. 1-6, a campaign implementation method includes establishing (a glitcher 631 or other) special-purpose controllers 131, 531 operably coupled to a local host 40, activated by a first triggering module 223. A first special-purpose controller 531A may be operably coupled with and configured to implement a first parametric sequence 526A upon a first unit in test 511A by virtue of the first special-purpose controller 531A deterministically generating numerous glitch attempt parameters 283 partly based on a local seed 122 and partly based on remotely provided device-executable code 284.

Contemporaneously with this implementation, in some variants second and third special-purpose controllers 531B-C are configured to implement one or more other parametric sequences 526B-C upon other UITs 511B-C by virtue of each of the controllers 531B-C deterministically generating its glitch attempt parameters 283 likewise partly based on a local seed 122 and partly based on remotely provided device-executable code 284.

The campaign implementation method also includes obtaining, by a first monitoring module 226 at the local host 40, a first test result 128 indicating one or more flaw-indicative anomalies 287 of the first parametric sequence 526A upon the first UIT 511A and one or more normalcy indications 178 of the third parametric sequence 526C upon a third UIT 511C.

The campaign implementation method also includes causing, by a first control module at the local host 40 the second special-purpose controller 531B to implement the first parametric sequence 526A upon the second UIT 511B in lieu of implementing the third parametric sequence 526C upon the second UIT 511B partly based on the one or more flaw-indicative anomalies 287 of the first parametric sequence 526A upon the first UIT 511A and partly based on the one or more normalcy indications 178 of the third parametric sequence 126, 526 upon the third UIT 511C.

Alternatively or additionally the above-described methods may include implementing at least the first special-purpose controller 531A as a special-purpose glitcher 631 and using a campaign setup protocol 105F that determines one or more upcoming glitch parameters 283, arming the special-purpose glitcher, resetting the first UIT 511A, and conducting pre-glitch communications with the first UIT 511A.

Alternatively or additionally the above-described methods may include implementing at least the first special-purpose controller 531A as a special-purpose glitcher 631 and using an outcome distillation protocol 105B that includes conducting post-glitch communications with the first UIT 511A, selectively disregarding one or more user-specified types of anomalies 287 (e.g. those matching a pattern deemed harmless by a manufacturer of the UITs), and storing one or more data distillation results 128.

Alternatively or additionally the above-described methods may include configuring the first special-purpose controller 531A to generate more than 80% of its operating parameters 283 (e.g. according to one or more respective scalar quantity counts) internally using a deterministic parameter generation protocol 105C (e.g. a pseudo random number generator based on a client-provided seed 460) in which a parametric sequence 526 containing more than 100 timing parameters 283 (e.g. as a nonzero scalar quantity count) are generated and applied without transmitting the parametric sequence 526 to the first special-purpose controller 531A.

Alternatively or additionally the above-described methods may include using a glitcher-containing controller 531B configured to control (at least) a power supply of the second UIT 511B.

Alternatively or additionally the above-described methods may include using a scoring protocol 105D that responds to the one or more flaw-indicative anomalies 287 (at least) at the first special-purpose controller 131A and using a machine learning protocol 105E invoked by the local host 40 that adjusts one or more subsequent glitch attempt parameters 283 that are thereafter applied via the second special-purpose controller 131B.

Alternatively or additionally the above-described methods may be streamlined by having configured a particular UIT 111C having (e.g. by firmware-calibrated or other) deterministic special-purpose circuitry 422 therein configured to generate more than 50% of the deployment-specific adjustable glitch attempt parameters 283 aboard the particular UIT 111C that are used in the particular UIT 111C so as to avoid any need for an inter-device transmission of those parameters 283 to or from the particular UIT 111C while a corresponding particular special-purpose controller 131C operably coupled with the particular UIT 111C remains installed in a locally deployed nest 130. This can occur, for example, in a context in which one or more seeds 460 (at least partly) determine more than 50% of those deployment-specific adjustable glitch attempt parameters 283 and in which sharing one or more of those seeds 460 allows a remote entity 140 to derive those deployment-specific adjustable glitch attempt parameters 283 were or will be used in the nest 130 without needing an inter-device transmission of most glitch attempt parameters 283 that are used in a particular UIT 111C to or from its corresponding particular special-purpose controller 131C. This can occur, for example, in a context in which one or more bandwidth-limited passive-media (wireless or other) linkages 177 are the only data handling paths that connect the particular UIT 111C with its corresponding particular special-purpose controller 131C; in which such deployment-specific adjustable glitch attempt parameters 283 that are generated and used aboard the particular UIT 111C partly based on the deterministic special-purpose circuitry 422 and partly based on the one or more seeds 460 would otherwise need to be transmitted via the one or more bandwidth-limited passive-media linkages 177 to or from the particular UIT 111C; and in which a project delay reduction corresponding to omitting such inter-device transmissions of most glitch attempt parameters 283 exceeds 1% of a total connection time during which the particular UIT 111C is operably coupled with its corresponding particular special-purpose controller 131C.

Alternatively or additionally the particular special-purpose controller 131C may be configured with a first plurality of the deployment-specific adjustable glitch attempt parameters 283 selectively implementing a digital-to-analog-converter-type glitch sequence 526 upon the particular UIT 111C, with a second plurality of the deployment-specific adjustable glitch attempt parameters 283 selectively implementing a crowbar-switching-type glitch sequence 526 upon the particular UIT 111C, with a third plurality of the deployment-specific adjustable glitch attempt parameters 283 selectively implementing a power-supply-muxing-type glitch sequence 526 upon the particular UIT 111C, and with a fourth plurality of

the deployment-specific adjustable glitch attempt parameters 283 selectively implementing an external-wire-gauge-switching-type glitch sequence 526 upon the corresponding particular UIT 111C all while the particular special-purpose controller 131C remains operably coupled with the particular UIT 111C. Alternatively or additionally, in some variants a campaign may feature an array of other programmatic glitch types used as described herein.

Alternatively or additionally the above-described methods may be streamlined by omitting an inter-device transmission of most non-anomalous test outcomes 267. This may be accomplished by one or more of the glitcher-containing controllers 131, 531 performing “significant” compression (i.e. with a median or nominal data compression ratio X that is greater than 10%) upon test outcome data 280 resulting from non-anomalous test outcomes 267 but with much less compression (i.e. with a non-zero median or nominal data compression ratio less than X/2) upon test outcome data 280 resulting from anomalous test outcomes 267. Alternatively or additionally this may be accomplished by such glitcher-containing controllers 131, 531 programmatically down-sampling or otherwise implementing “significantly selective” retention (i.e. with a fractional data reduction Y that is greater than 10%) upon raw or other tracking data 280 resulting from non-anomalous test outcomes 267 but with little or no selectivity (i.e. with a fractional data reduction less than Y/2) upon instances of test outcome data 280 resulting from out-of-range or otherwise (nominally) anomalous test outcomes 267. This can occur, for example, in a context in which an owner of the UITs 111, 511 has authorized such selectivity as a temporary departure from an established outcome distillation protocol 105B that allows testing completion on a timetable that would otherwise be impossible in a given testing nest 130.

Alternatively or additionally the above-described methods may feature numerous glitcher-containing controllers 131, 531 contemporaneously operating so as to accelerate a parallel product validation of numerous UITs 111, 511. Alternatively or additionally the above-described methods may feature numerous glitcher-containing controllers 531 contemporaneously implementing testing or other outcome distillation protocols 105B at a large enough scale so as to permit a confirmed result 128 that an observed anomaly 287 includes an intermittency 286 at a first confidence level.

Alternatively or additionally such testing or other outcome distillation protocols 105B may be implemented at a large enough scale so as to permit a confirmed result 128 that another (instance of an) observed anomaly 287 does not include an intermittency 286 at a respectively suitable confidence level.

In light of teachings herein, those skilled in the art will understand how to configure and improve such protocols and models without any undue experimentation. While various system, method, article of manufacture, or other embodiments or aspects have been disclosed above, also, other combinations of embodiments or aspects will be apparent to those skilled in the art in view of the above disclosure. The various embodiments and aspects disclosed above are for purposes of illustration and are not intended to be limiting.

In the numbered clauses below, combinations of aspects and embodiments are articulated herein in a shorthand form such that (1) according to respective embodiments, for each instance in which a “component” or other such identifiers appear to be introduced (e.g., with “a” or “an,”) more than once in a given chain of clauses, such designations may either identify the same entity or distinct entities; and (2) what might be called “dependent” variants may or may not incorporate, in respective embodiments, the features of embodiments to which they refer or other features described above.

### CLAUSES

Clause 1. A coordinated validation method comprising:
invoking first transistor-based circuitry (e.g. a download and triggering module 222, 223 jointly) configured to establish numerous special-purpose controllers 131 operably coupled to a single local host 40 that include a first special-purpose controller 131A operably coupled with and configured to implement a first parametric sequence 126 upon a first unit in test (UIT) 111A and that include a second special-purpose controller 131B operably coupled with and configured to implement a second parametric sequence 126 upon a second UIT 111B by virtue of the second special-purpose controller 131B deterministically generating (contemporaneously or otherwise) its glitch attempt parameters 283 likewise based on the device-executable code 284;
invoking second transistor-based circuitry (e.g. a monitoring module 226) configured to obtain a first test result 128 indicating one or more flaw-indicative anomalies 287 of the first parametric sequence 126 upon the first UIT 111A; and
invoking third transistor-based circuitry (e.g. an instance of a control or update module 224, 225) configured to cause the second special-purpose controller 131B to implement the first
parametric sequence 126 upon the second UIT 111B (at least partly) based on the one or more flaw-indicative anomalies 287 of the first parametric sequence 126 upon the first UIT 111A.
   Clause 2. The method of Clause 1 comprising:
invoking fourth transistor-based circuitry (e.g. an instance of a triggering module 223) configured to trigger a scoring protocol 105D that responds to the one or more flaw-indicative anomalies 287 (at least) at the first special-purpose controller 131A as a (local or other) component of a machine learning protocol 105E that adjusts one or more subsequent glitch attempt parameters 283 that are thereafter applied via the second special-purpose controller 131B.
   Clause 3. The method of any one of the above Clauses comprising:
causing the second special-purpose controller 131B to implement the first parametric sequence 126 upon the second UIT 111B partly based on the one or more flaw-indicative anomalies 287 of the first parametric sequence 126 upon the first UIT 111A and partly based on an explicit or other indication 178 that no flaw-indicative anomalies 287 have yet been detected (directly or otherwise) by the second special-purpose controller 131B.
   Clause 4. The method of any one of the above Clauses wherein a third UIT 111C has deterministic special-purpose circuitry 422 therein configured to generate more than 50% of glitch attempt parameters 283 aboard the third UIT 111C that are eventually used in testing the third UIT 111C so as to avoid any need for an inter-device transmission of most said glitch attempt parameters 283 to or from the third UIT 111C while a corresponding third special-purpose controller 131C is operably coupled with the third UIT 111C remains installed in a locally deployed nest 130 that includes the first and second special-purpose controllers 131A-B.
   Clause 5. The method of any one of the above Clauses wherein a third UIT 111C has deterministic special-purpose circuitry 422 therein configured to generate more than 50% of glitch attempt parameters 283 aboard the third UIT 111C that are eventually used in testing the third UIT 111C while a corresponding third special-purpose controller 131C is operably coupled with the third UIT 111C remains installed in a locally deployed nest 130 that includes the first and second special-purpose controllers 131A-B.
   Clause 6. The method of any one of the above Clauses wherein the method is streamlined by using one or more seeds 460 in locally generating, using, and deleting most of said glitch attempt parameters 283 used for testing the first UIT 111A in a single campaign aboard the first UIT 111A without ever subjecting each of said glitch attempt parameters 283 to any inter-device transmission.
   Clause 7. The method of any one of the above Clauses wherein the method is streamlined by using one or more seeds 460 in locally generating, using, and deleting most of said glitch attempt parameters 283 used for testing the first UIT 111A in a single campaign aboard the first UIT 111A without ever subjecting each non-anomalous test outcome 267 associated with said glitch attempt parameters 283 to any inter-device transmission.
   Clause 8. The method of any one of the above Clauses wherein one or more seeds 460 effectively determine more than 50% of deployment-specific adjustable glitch attempt parameters 283.
   Clause 9. The method of any one of the above Clauses wherein one or more seeds 460 determine more than 50% of deployment-specific adjustable glitch attempt parameters 283 and wherein sharing one or more of those seeds 460 allows a remote entity 140 to derive those deployment-specific adjustable glitch attempt parameters 283 were or will be used in a locally deployed nest 130 that includes the first and second special-purpose controllers 131A-B without needing an inter-device transmission of most glitch attempt parameters 283 that are used in one or more local UIT's 111 to or from its corresponding special-purpose controller 131C.
   Clause 10. The method of any one of the above Clauses wherein one or more seeds 460 determine more than 50% of deployment-specific adjustable glitch attempt parameters 283 and wherein sharing one or more of the seeds 460 allows a remote entity 140 to derive more than 50% of deployment-specific adjustable glitch attempt parameters 283 that were or will be used in the nest 130.
   Clause 11. The method of any one of the above Clauses wherein one or more seeds 460 determine more than 50% of deployment-specific adjustable glitch attempt parameters 283 and wherein one or more passive-media (wireless or other) linkages 177 are the only data handling paths that connect a third UIT 111C with a corresponding third special-purpose controller 131C.
   Clause 12. The method of any one of the above Clauses wherein one or more seeds 460 determine more than 50% of deployment-specific adjustable glitch attempt parameters 283 and wherein the deployment-specific adjustable glitch attempt parameters 283 that are generated and used aboard the third UIT 111C would otherwise need to be transmitted via the one or more bandwidth-limited passive-media linkages 177 to or from the third UIT 111C.
   Clause 13. The method of any one of the above Clauses wherein a project delay reduction corresponding to omitting the inter-device transmissions of most of the glitch attempt parameters 283 exceeds 1% of a total connection time during which the third UIT 111C is operably coupled with the third special-purpose controller 131C.
   Clause 14. The method of any one of the above Clauses comprising:
causing the second special-purpose controller 131B to implement the first parametric sequence 126 upon the second UIT 111B partly based on the one or more flaw-indicative anomalies 287 of the first parametric sequence 126 upon the first UIT 111A and partly based on one or more normalcy indications 178 of an outcome of the third parametric sequence 526C upon the third UIT 111, 511.
   Clause 15. The method of any one of the above Clauses wherein the second and third special-purpose controllers 531B-C are configured to implement one or more other parametric sequences 526B-C upon one or more other UITs 511B-C by virtue of each of the controllers 531B-C deterministically generating its respective glitch attempt parameters 283 likewise partly based on a (UIT-specific, host-specific, or other) local seed 122 and partly based on second remotely provided device-executable code 284.
   Clause 16. The method of any one of the above Clauses wherein the second and third special-purpose controllers 531B-C are configured to implement one or more other parametric sequences 526B-C upon one or more other UITs 511B-C by virtue of each of the controllers 531B-C deterministically generating its one or more glitch attempt parameters 283 using a local seed 122 that includes a campaign-specific component.
   Clause 17. The method of any one of the above Clauses wherein the second and third special-purpose controllers 531B-C are configured to implement one or more other parametric sequences 526B-C upon one or more other UITs 511B-C by virtue of each of the controllers 531B-C deterministically generating its one or more glitch attempt parameters 283 using a local seed 122 that includes a secret component that is kept locally (e.g. in a testing nest 130).
   Clause 18. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a secret campaign-specific component that is kept locally.
   Clause 19. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that was generated stochastically and retained within the second UIT 511B.
   Clause 20. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that was generated stochastically and retained within a nest 130 that includes the first and second UITs 511A-B.
   Clause 21. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a UIT-specific component.
   Clause 22. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a secret UIT-specific component that is kept locally.
   Clause 23. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a secret testing-site-specific component that is kept locally.
   Clause 24. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a nest-specific component.
   Clause 25. The method of any one of the above Clauses wherein the second special-purpose controller 531B is configured to implement one or more other parametric sequences 526B upon a second UIT 511B by virtue of a second controller 531B deterministically generating its one or more glitch attempt parameters 283 using a local seed 122 that includes a secret nest-specific component that is kept locally.
   Clause 26. The method of any one of the above Clauses wherein an outcome distillation protocol 105B is implemented that includes conducting post-glitch communications with the first UIT 511A, selectively disregarding one or more user-specified types of anomalies 287 (e.g. those matching a pattern deemed harmless by a manufacturer of the UITs), and storing one or more data distillation results 128.
   Clause 27. The method of any one of the above Clauses wherein a glitcher-containing the second special-purpose controller 531B is configured to control a power supply of the second UIT 511B and wherein a campaign setup protocol 105F is used for testing (at least) the second UIT 511B that includes obtaining the one or more upcoming glitch parameters 283, arming the second special-purpose glitcher 631, resetting the second UIT 511B, and conducting pre-glitch communications with the second UIT 511B.
   Clause 28. The method of any one of the above Clauses wherein one or more seeds 460 determine more than 50% of one or more upcoming glitch parameters 283 aboard the second UIT 511B and wherein a campaign setup protocol 105F is used for testing the second UIT 511B that includes obtaining the one or more upcoming glitch parameters 283, arming the second special-purpose glitcher 631, resetting the second UIT 511B, and conducting pre-glitch communications with the second UIT 511B.
   Clause 29. The method of any one of the above Clauses wherein one or more seeds 460 determine more than 50% of one or more upcoming glitch parameters 283 aboard the second UIT 511B and wherein a glitcher-containing the second special-purpose controller 531B is configured to control (at least) a power supply of the second UIT 511B.
   Clause 30. The method of any one of the above Clauses wherein the first special-purpose controller 531A is configured to generate more than 80% of its operating parameters 283 internally using a deterministic parameter generation protocol 105C (e.g. a pseudo random number generator based on a client-provided seed 460) and wherein a parametric sequence 526 containing more than 100 timing parameters 283 are generated and applied at the first special-purpose controller 531A without the parametric sequence 526 being transmitted to the first special-purpose controller 531A.
   Clause 31. The method of any one of the above Clauses wherein in the first test result 128 indicating the one or more flaw-indicative anomalies 287 of the first parametric sequence 126 upon the first UIT 111A is obtained after the first special-purpose controller 131A is configured as a first special-purpose glitcher 631 and whereby a campaign setup protocol 105F is used so as to determine one or more upcoming glitch parameters 283, so as to arm the first special-purpose glitcher 631, so as to reset the first UIT 511A, and so as to conduct pre-glitch communications with the first UIT 511A.
   Clause 32. The method of any one of the above Clauses wherein the first test result 128 indicating the one or more flaw-indicative anomalies 287 of the first parametric sequence 126 upon the first UIT 111A is obtained by configuring the first special-purpose controller 131A as a first special-purpose glitcher 631 and whereby a campaign setup protocol 105F is used so as to determine one or more upcoming glitch parameters 283, so as to arm the first special-purpose glitcher 631, so as to reset the first UIT 511A, and so as to conduct pre-glitch communications with the first UIT 511A.
   Clause 33. The method of any one of the above Clauses wherein the first test result 128 indicating the one or more flaw-indicative anomalies 287 of the first parametric sequence 126 upon the first UIT 111A is obtained by configuring the first special-purpose controller 131A as a first special-purpose glitcher 631.
   Clause 34. The method of any one of the above Clauses wherein a campaign setup protocol 105F is used for (at least) the second UIT 511B that includes obtaining the one or more upcoming glitch parameters 283, arming the second special-purpose glitcher 631, resetting the second UIT 511B, and conducting pre-glitch communications with the second UIT 511B.
   Clause 35. The method of any one of the above Clauses wherein the third special-purpose controller 131C is configured with a plurality of the deployment-specific adjustable glitch attempt parameters 283 selectively implementing a digital-to-analog-converter-type glitch sequence 526 upon a corresponding third UIT 111C.
   Clause 36. The method of any one of the above Clauses wherein the third special-purpose controller 131C is configured with a plurality of the deployment-specific adjustable glitch attempt parameters 283 selectively implementing a crowbar-switching-type glitch sequence 526 upon the corresponding particular UIT 111C.
   Clause 37. The method of any one of the above Clauses wherein the third special-purpose controller 131C is configured with a plurality of the deployment-specific adjustable glitch attempt parameters 283 selectively implementing a digital-to-analog-converter-type glitch sequence 526 or a crowbar-switching-type glitch sequence 526 (or both) upon the corresponding particular UIT 111C.
   Clause 38. The method of any one of the above Clauses wherein the third special-purpose controller 131C is configured with a plurality of the deployment-specific adjustable glitch attempt parameters 283 selectively implementing a power-supply-muxing-type glitch sequence 526 upon the corresponding third UIT 111C.
   Clause 39. The method of any one of the above Clauses wherein the third special-purpose controller 131C is configured with a plurality of the deployment-specific adjustable glitch attempt parameters 283 selectively implementing an external-wire-gauge-switching-type glitch sequence 526 upon the corresponding third UIT 111C.
   Clause 40. The method of any one of the above Clauses wherein the third special-purpose controller 131C is configured with a plurality of the deployment-specific adjustable glitch attempt parameters 283 selectively implementing a power-supply-muxing-type glitch sequence 526 or an external-wire-gauge-switching-type glitch sequence 526 (or both) upon the corresponding third UIT 111C all while a corresponding third special-purpose controller 131C remains operably coupled with the third UIT 111C.
   Clause 41. The method of any one of the above Clauses wherein the method is streamlined (at least) by virtue of one or more of the controllers 131, 531 performing a first degree of compression upon test outcome data 280 resulting from non-anomalous test outcomes 267 but with a lesser second degree of compression upon test outcome data 280 resulting from anomalous test outcomes 267.
   Clause 42. The method of any one of the above Clauses wherein the method is streamlined by virtue of the controllers 131, 531 programmatically down-sampling or otherwise implementing significantly selective retention with a fractional data reduction Y that is greater than 10% upon raw or other tracking data 280 (e.g. in bytes) resulting from non-anomalous test outcomes 267 but with temporarily reduced selectivity upon instances of test outcome data 280 resulting from out-of-range or otherwise (nominally) anomalous test outcomes 267 in a context in which the temporarily reduced selectivity manifests a temporary departure from an established outcome distillation protocol 105B and that thereby enables testing completion on a timetable that would otherwise be impossible in a given testing nest 130.
   Clause 43. The method of any one of the above Clauses wherein the method is streamlined (at least) by virtue of the controllers 131, 531 programmatically down-sampling or otherwise implementing significantly selective retention with a fractional data reduction Y that is greater than 10% upon raw or other tracking data 280 (e.g. in bytes) resulting from non-anomalous test outcomes 267 but with less selectivity upon instances of test outcome data 280 resulting from out-of-range or otherwise (nominally) anomalous test outcomes 267.
   Clause 44. The method of any one of the above Clauses wherein the method is streamlined by virtue of numerous glitcher-containing controllers 531 including said special-purpose controllers are contemporaneously implementing (testing or other) outcome distillation protocols 105B at a large enough scale so as to permit a confirmed result 128 that an observed anomaly 287 includes an intermittency 286 at a first confidence level to occur.
   Clause 45. The method of any one of the above Clauses wherein the method is streamlined (at least) by virtue of numerous glitcher-containing controllers 531 including said special-purpose controllers are contemporaneously implementing (testing or other) outcome distillation protocols 105B at a large enough scale so as to permit a confirmed result 128 that an observed anomaly 287 includes an intermittency 286 at a first confidence level to occur.
   Clause 46. A system 100, 200, 600 configured to perform any method of the above Clauses.
   Clause 47. A system 100, 200, 600 configured to facilitate any method of the above Clauses.
   Clause 48. A coordinated validation system comprising:
first transistor-based circuitry (e.g. a download and triggering module 222, 223 jointly) configured to establish numerous special-purpose controllers 131 operably coupled to a single local host 40 that include a first special-purpose controller 131A operably coupled with and configured to implement a first parametric sequence 126 upon a first unit in test (UIT) 111A and that include a second special-purpose controller 131B operably coupled with and configured to implement a second parametric sequence 126 upon a second UIT 111B by virtue of the second special-purpose controller 131B deterministically generating (contemporaneously or otherwise) its glitch attempt parameters 283 likewise based on the device-executable code 284;
second transistor-based circuitry (e.g. a monitoring module 226) configured to obtain a first test result 128 indicating one or more flaw-indicative anomalies 287 of the first parametric sequence 126 upon the first UIT 111A; and
third transistor-based circuitry (e.g. an instance of a control or update module 224, 225) configured to cause the second special-purpose controller 131B to implement the first parametric sequence 126 upon the second UIT 111B (at least partly) based on the one or more flaw-indicative anomalies 287 of the first parametric sequence 126 upon the first UIT 111A.

With respect to the numbered claims expressed below, those skilled in the art will appreciate that recited operations therein may generally be performed in any order. Also, although various operational flows are presented in sequence(s), it should be understood that the various operations may be performed in other orders than those which are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Terms like “responsive to,” “related to,” or other such transitive, relational, or other connections do not generally exclude such variants, unless context dictates otherwise. Furthermore each claim below is intended to be given its least-restrictive interpretation that is reasonable to one skilled in the art.

What is claimed is:

1. An adaptively parallelized coordinated validation method comprising:
invoking first transistor-based circuitry configured to establish numerous special-purpose controllers operably coupled to a single local host that include a first special-purpose controller operably coupled with and configured to implement a first parametric sequence upon a first unit in test (UIT) at least by virtue of said first special-purpose controller deterministically generating numerous respective sets of glitch attempt parameters based on first device-executable code provided by a remote entity and configured locally and that include a second special-purpose controller operably coupled with and configured to implement a second parametric sequence upon a second UIT by virtue of said second special-purpose controller deterministically generating its glitch attempt parameters likewise based on said first device-executable code;
automatically invoking second transistor-based circuitry configured to obtain a first test result indicating one or more flaw-indicative anomalies of said first parametric sequence upon said first UIT; and
automatically invoking third transistor-based circuitry configured to cause said second special-purpose controller to implement said first parametric sequence upon said second UIT partly based on said one or more flaw-indicative anomalies of said first parametric sequence upon said first UIT and partly based on an indication that no flaw-indicative anomalies have yet been detected by said second special-purpose controller.

2. The method of claim 1 comprising:
invoking fourth transistor-based circuitry configured to trigger a scoring protocol that responds to said one or more flaw-indicative anomalies at said first special-purpose controller as a component of a machine learning protocol that adjusts one or more subsequent glitch attempt parameters that are thereafter applied via said second special-purpose controller.

3. The method of claim 1 wherein one or more seeds determine more than 50% of deployment-specific adjustable glitch attempt parameters and wherein said deployment-specific adjustable glitch attempt parameters that are generated and used aboard a third UIT would otherwise need to be transmitted via said one or more bandwidth-limited passive-media linkages to or from said third UIT.

4. The method of claim 1 comprising:
causing said second special-purpose controller to implement said first parametric sequence upon said second UIT partly based on said one or more flaw-indicative anomalies of said first parametric sequence upon said first UIT and partly based on one or more normalcy indications of an outcome of said third parametric sequence upon a third UIT.

5. The method of claim 1 wherein said method is streamlined by virtue of said first and second special-purpose controllers programmatically down-sampling or otherwise implementing significantly selective retention with a fractional data reduction Y that is greater than 10% upon raw or other tracking data resulting from non-anomalous test outcomes but with temporarily reduced selectivity upon instances of test outcome data resulting from out-of-range or otherwise anomalous test outcomes in a context in which said temporarily reduced selectivity manifests a temporary departure from an established outcome distillation protocol and that thereby enables testing completion on a timetable that would otherwise be impossible in a given testing nest.

6. The method of claim 1 wherein said second special-purpose controller and a third special-purpose controller of said numerous special-purpose controllers are configured to implement one or more other parametric sequences upon one or more other UITs by virtue of said second and third special-purpose controllers each deterministically generating its respective glitch attempt parameters partly based on a local seed and partly based on second device-executable code.

7. The method of claim 1 wherein an outcome distillation protocol is implemented that includes conducting post-glitch communications with said first UIT, selectively disregarding one or more user-specified types of anomalies, and storing one or more data distillation results.

8. The method of claim 1 wherein said method is streamlined by using one or more seeds in locally generating, using, and deleting most of said glitch attempt parameters used for testing said first UIT in a single campaign aboard said first UIT without ever subjecting each non-anomalous test outcome associated with said glitch attempt parameters to any inter-device transmission.

9. The method of claim 1 wherein a glitcher-containing third special-purpose controller of said numerous special-purpose controllers is configured to control a power supply of a third UIT and wherein a campaign setup protocol is used for testing said third UIT that includes obtaining said one or more upcoming glitch parameters, arming said second special-purpose glitcher, resetting said third UIT, and conducting pre-glitch communications with said third UIT.

10. The method of claim 1 wherein said first special-purpose controller is configured to generate more than 80% of its operating parameters internally using a deterministic parameter generation protocol and wherein a parametric sequence containing more than 100 timing parameters are generated and applied at said first special-purpose controller without said parametric sequence being transmitted to said first special-purpose controller.

11. The method of claim 1 wherein a third special-purpose controller of said numerous special-purpose controllers is configured with a plurality of said deployment-specific adjustable glitch attempt parameters selectively implementing a digital-to-analog-converter-type glitch sequence or a crowbar-switching-type glitch sequence upon a third UIT.

12. The method of claim 1 wherein a third special-purpose controller of said numerous special-purpose controllers is configured with a plurality of said deployment-specific adjustable glitch attempt parameters selectively implementing a power-supply-muxing-type glitch sequence or an external-wire-gauge-switching-type glitch sequence upon a third UIT all while said third special-purpose controller remains operably coupled with said third UIT.

13. The method of claim 1 wherein said method is streamlined by virtue of one or more of said special-purpose controllers performing a first degree of compression upon test outcome data resulting from non-anomalous test outcomes but with a lesser second degree of compression upon test outcome data resulting from anomalous test outcomes.

14. The method of claim 1 wherein a third UIT has deterministic special-purpose circuitry therein configured to generate more than 50% of glitch attempt parameters aboard said third UIT that are eventually used in testing said third UIT so as to avoid any need for an inter-device transmission of most said glitch attempt parameters to or from said third UIT while a third special-purpose controller of said numerous special-purpose controllers is operably coupled with said third UIT and remains installed in a locally deployed nest that includes said first and second special-purpose controllers.

15. The method of claim 1 wherein one or more seeds determine more than 50% of deployment-specific adjustable glitch attempt parameters and wherein sharing one or more of those seeds allows a remote entity to derive those deployment-specific adjustable glitch attempt parameters were or will be used in a locally deployed nest that includes said first and second special-purpose controllers without needing an inter-device transmission of most glitch attempt parameters that are used in one or more other UIT's to or from a corresponding special-purpose controller.

16. The method of claim 1 wherein one or more seeds determine more than 50% of deployment-specific adjustable glitch attempt parameters and wherein sharing one or more of said seeds allows a remote entity to derive more than 50% of deployment-specific adjustable glitch attempt parameters that were or will be used in said nest.

17. A coordinated validation method comprising:
invoking first transistor-based circuitry configured to establish numerous special-purpose controllers operably coupled to a single local host that include a first special-purpose controller operably coupled with and configured to implement a first parametric sequence upon a first unit in test (UIT) and that include a second special-purpose controller operably coupled with and configured to implement a second parametric sequence upon a second UIT by virtue of said second special-purpose controller deterministically generating its glitch attempt parameters based on said first device-executable code;
invoking second transistor-based circuitry configured to obtain a first test result indicating one or more flaw-indicative anomalies of said first parametric sequence upon said first UIT; and
invoking third transistor-based circuitry configured to cause said second special-purpose controller to implement said first parametric sequence upon said second UIT partly based on said one or more flaw-indicative anomalies of said first parametric sequence upon said first UIT and partly based on an indication that no flaw-indicative anomalies have yet been detected by said second special-purpose controller.

18. A computer program product comprising:
one or more tangible, nonvolatile storage media; and
machine instructions borne on said one or more tangible, nonvolatile storage media which, when running on one or more computer systems, cause said one or more computer systems to perform said method of claim 17.

19. A coordinated validation system comprising:
first transistor-based circuitry configured to establish numerous special-purpose controllers operably coupled to a single local host that include a first special-purpose controller operably coupled with and configured to implement a first parametric sequence upon a first unit in test (UIT) and that include a second special-purpose controller operably coupled with and configured to implement a second parametric sequence upon a second UIT by virtue of said second special-purpose controller deterministically generating its glitch attempt parameters based on said first device-executable code;
second transistor-based circuitry configured to obtain a first test result indicating one or more flaw-indicative anomalies of said first parametric sequence upon said first UIT; and
third transistor-based circuitry configured to cause said second special-purpose controller to implement said first parametric sequence upon said second UIT partly based on said one or more flaw-indicative anomalies of said first parametric sequence upon said first UIT and partly based on an indication that no flaw-indicative anomalies have yet been detected by said second special-purpose controller.
